(19) United States
(12) Patent Application Publication
(10) Pub. No.: US 2012/0187267 A1
(43) Pub. Date: Jul. 26, 2012

(54) ADJUSTABLE MOUNTING BRACKET FOR A PHOTOVOLTAIC PANEL FRAME SYSTEM

(75) Inventors: John Hudson, Mableton, GA (US); Daniel Lee Hughes, Griffin, GA (US)

(73) Assignee: JAC-Rack, Inc., Pontiac, MI (US)

(21) Appl. No.: 13/014,191

(22) Filed: Jan. 26, 2011

(51) Int. Cl. H01L 23/12

(52) U.S. Cl. 248/292.14

(57) ABSTRACT

A bracket assembly for use with a photovoltaic panel frame system. The bracket assembly has an L-shaped member and a base member. A foot portion of the L-shaped member has a lower surface with an arcuate configuration and a plurality of teeth. The base member has an upper surface with an arcuate configuration similar or identical to that of the lower surface of the L-shaped member. The base member further includes a slot for enabling a shaft portion of a threaded fastening member to extend through, while the L-shaped member includes a hole for allowing the shaft portion of the threaded fastening member to pass there through. The teeth allow the L-shaped member and the base member to be quickly secured together so as to provide a desired degree of inclination of the L-shaped member relative to the base member. The slot enables a degree of adjustability between the L-shaped member and the base member so that the bracket assembly can be configured to provide various degrees of inclination to a PV panel being secured by the bracket assembly.

### TECHNICAL FIELD

The present disclosure relates generally to mounting brackets, and more particularly to mounting brackets used in frame systems for supporting photovoltaic panels on various types of support structures.

### BACKGROUND

This section provides background information related to the present disclosure, which is not necessarily prior art.

With photovoltaic (PV) panel frame systems, typically the PV panels have to be supported at a slight angle relative to the support surface that they are supported from. Typically a frame system is employed that makes use of a plurality of bracket assemblies and elongated metallic frame members. The metallic frame members are typically supported above a support surface such as a roof of a building, although the frame members could be supported from a ground based support structure. The metallic frame members and bracket assemblies form an assembly to which the PV panels can be attached so that the PV panels can be supported in a stable manner above the support surface.

When the PV panels are securely mounted to the support frame members, typically the PV panels are adjusted so that their surfaces will be normal, or near normal, to the sun's rays that impinge them. Most often this involves using different types of brackets that support the PV panels relative to the frame members (and the support surface) such that a predetermined inclination is provided to the PV panels relative to the support surface. The degree of inclination may vary considerably, but often is between about 0-20 degrees for ballast frame systems and between about 0-30 degrees for roof mounted frame systems. So if the installer knows that a 5 degree inclination is needed for a specific installation on a specific roof surface, the installer will need to have a suitable quantity of support brackets on hand when installing the PV panels and the frame system on the specific roof surface. Since residential and commercial buildings have roof surfaces with a wide degree of different pitches, a frame system manufacturer will typically need to maintain a stock of bracket assemblies that provide different degrees of inclination to suit the specific needs of each installation project. As will be appreciated, this can add significant cost and complexity for the manufacturer of the frame system. This can also complicate inventory management for the manufacturer since a wide variety of different bracket assemblies may need to be kept in stock to meet the needs of different installations.

### SUMMARY

In one aspect the present disclosure relates to a bracket system for use with a photovoltaic panel frame system. The bracket system may be used to assist in mounting at least one photovoltaic panel at an angle non-parallel to a support surface on which the photovoltaic panel frame system is mounted. The bracket system may include a bracket assembly having a first member and a second member. The first member may have a neck portion and a foot portion extending non-parallel to the neck portion, with the foot portion having a radius of curvature. The second member may have a first surface having a radius of curvature that generally matches the radius of curvature of the foot portion. One of the first member and the second member may have an elongated slot formed therein and the other one of the first member and the second member may have a hole formed therein. A fastener may be adapted to extend through the elongated slot and the hole to secure the first and second members fixedly to a frame system component, and further such that the first member can be secured at a desired inclination relative to the frame system component.

### BRIEF DESCRIPTION OF DRAWINGS

The drawings described herein are for illustrative purposes only of selected embodiments and not all possible implementations, and are not intended to limit the scope of the present disclosure.

FIG. 1 is a perspective view of a PV panel system mounted on a portion of a roof of a building via a PV panel frame system, and further illustrating that the PV panels of the system are being supported at a predetermined inclination relative to the roof surface of the building;

FIG. 2A is a perspective view of a bracket assembly in accordance with an embodiment of the present disclosure;

FIG. 2B is a side view of a bracket assembly adapted to be used along an elevated side of a PV panel;

FIG. 2C is a side view of a portion of the bracket assembly of FIG. 1 being used with an extension component to provide additional overall length thereto, with one end of the extension component being secured to one of the frame members shown in FIG. 1;

FIG. 3 is a top view of the bracket assembly of FIG. 2;

FIG. 4 is a front view of the bracket assembly of FIG. 2;

FIG. 5 is a side view of the bracket assembly of FIG. 2 being used to support a frame member of the frame system of FIG. 1, with an L-shaped member positioned at one extreme end of its travel to provide no amount of inclination;

FIG. 6 is a side view of the bracket assembly of FIG. 3 but with the L-shaped member positioned at its opposite extreme position to provide a maximum degree of inclination, which in this example is 10.0 degrees of inclination;

FIG. 7 is an enlarged side view of a Detail A shown in FIG. 5 more fully illustrating the engagement of teeth on the L-shaped member and a plurality of teeth of a base portion of the bracket assembly;

FIG. 8 is a side view of a washer of the bracket assembly; and

FIG. 9 is a top view of the washer of FIG. 7.

Corresponding reference numerals indicate corresponding parts throughout the several views of the drawings.

### DETAILED DESCRIPTION

Example embodiments will now be described more fully with reference to the accompanying drawings.

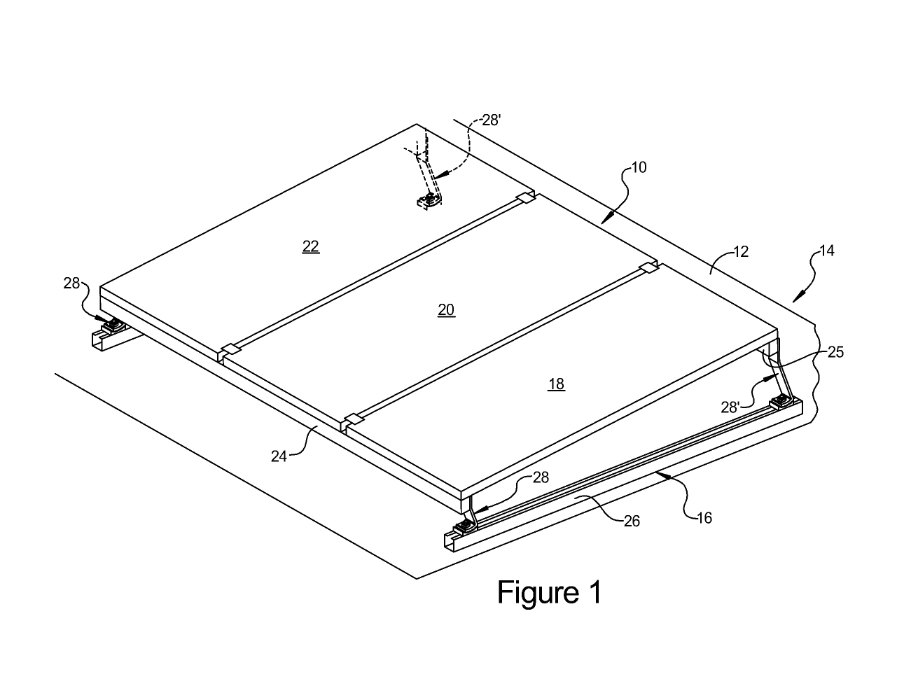

Referring now to FIG. 1, there is shown a PV panel system 10 mounted on a roof 12 of a building 14 via a PV frame system 16. The building 14 could instead be a residential dwelling. Still further, the PV panel system 10 could be mounted on a ground surface structure, for example on one or more concrete pads that are formed on a ground surface. As such, the bracket assembly of the present disclosure is not limited to use in only one specific type of application or with just one specific type of building or residence, but rather is readily adaptable for use with a wide variety of support structures.

The PV panel system 10 in this example includes three PV panels 18, and 22 that are mounted closely adjacent one another. A pair of elongated frame members 24 and a pair of end frame members 26 form the PV frame system 16. Each of the frame members 24 and 26 preferably have integrally formed channels and are disposed to form a suitably shaped support framework. The frame system 16 enables the PV panels 18-22 to be supported thereon via a plurality of bracket assemblies 28 of the present disclosure along a frame member 24, and via a plurality of bracket assemblies 28′ along the frame member 25. This enables the PV panels 18, 20 and 22 to be supported non-parallel to the roof 12 of the building 14 with frame member 25 being at a higher elevation than frame member 24. The elongated frame members 24 and 25 and 26, as well as the end frame members 26, may each be secured to the roof 12 via a plurality of conventional mounting assemblies (not shown) that secure to the trusses of the roof 12, or by any other suitable structure. The bracket assemblies 28,28′ provide an adjustable degree of inclination to the PV panels 18-22 relative to the roof 12. As will be explained in further detail, the bracket assemblies 28,28′ may be secured by threaded bolts and nuts that engage within channels of the frame members 24 and/or 26.

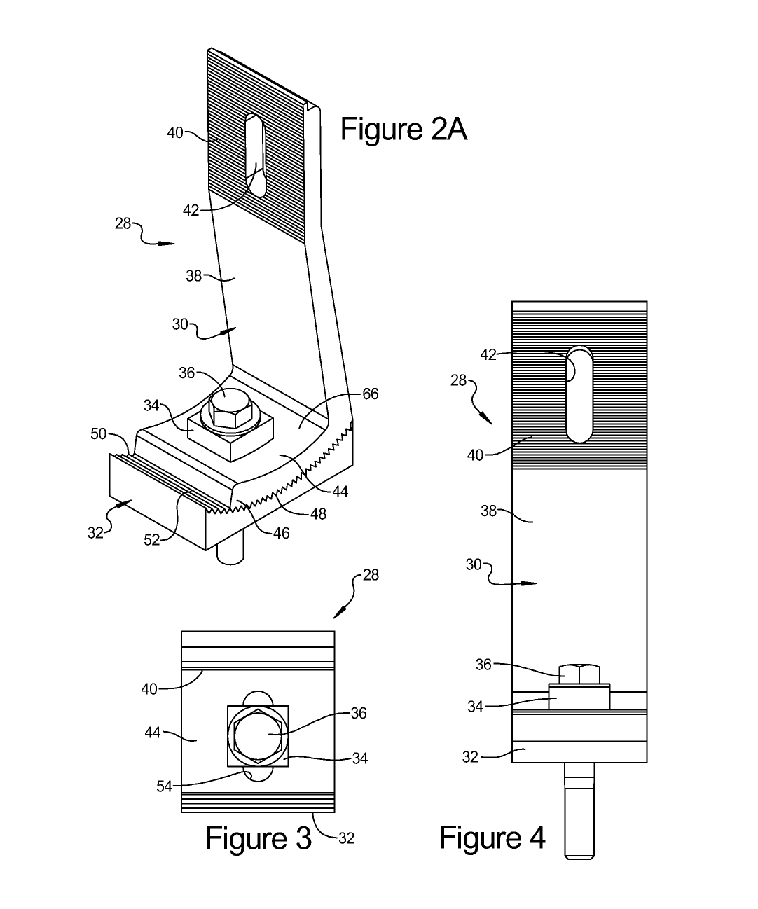

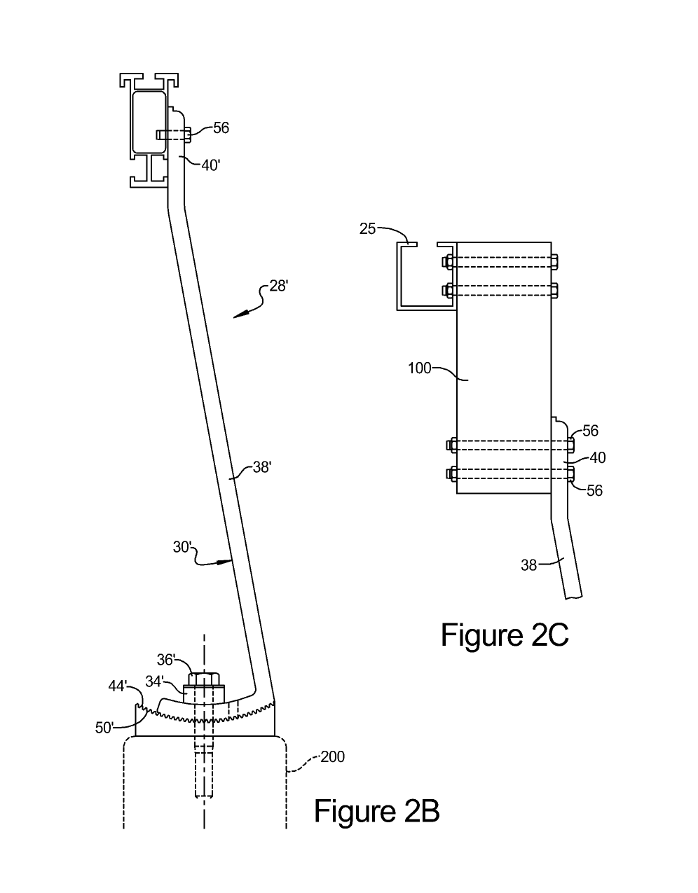

Referring now to FIGS. 2A and 3-6, one of the bracket assemblies 28 can be seen in greater detail. Each bracket assembly 28 is intended to be used along the elevationally lower edge of the PV panels 18-22, and therefore is coupled to the frame member 24. Each bracket assembly 28 generally includes an L-shaped member 30, a base member 32, a washer 34 and a threaded bolt 36. The L-shaped member 30 includes a neck portion 38 having a head portion 40 with a vertically arranged slot 42. The head portion 40 may include a plurality of serrations, and typically is slightly offset from the remainder of the neck portion 38 as seen in FIGS. 2, 4, 5 and 6. A foot portion 44 of the L-shaped member 30 includes a lower surface 46 having a plurality of teeth 48. The foot portion 44 may be arcuately shaped to have a radius of curvature. The radius of curvature may vary significantly to meet the needs of a specific application, but it is anticipated that the radius of curvature for most implementations of the bracket assemblies 28 will range between about 2-10 inches.

The base member 32 includes an upper surface 50 that is formed in an arc having a radius of curvature which is the same as the radius of curvature of the foot portion 44 of the L-shaped member 30. The upper surface 50 similarly includes a plurality of teeth 52 that engage with the teeth 48 of the L-shaped member 30 to positively hold the L-shaped member 30 at a predetermined angular orientation relative to the base member 32 when the two components are secured together by the threaded bolt 36 to one of the frame members 24.

With brief reference to FIG. 3, the foot portion 44 of the L-shaped member 30 can also be seen to include a slot 54 formed therein. The slot 54 has a width sufficient to allow a shaft portion of the threaded bolt 36 to pass there through. The slot 54 has a length that controls the maximum degree of inclination of the L-shaped component 30 relative to the base member 32.

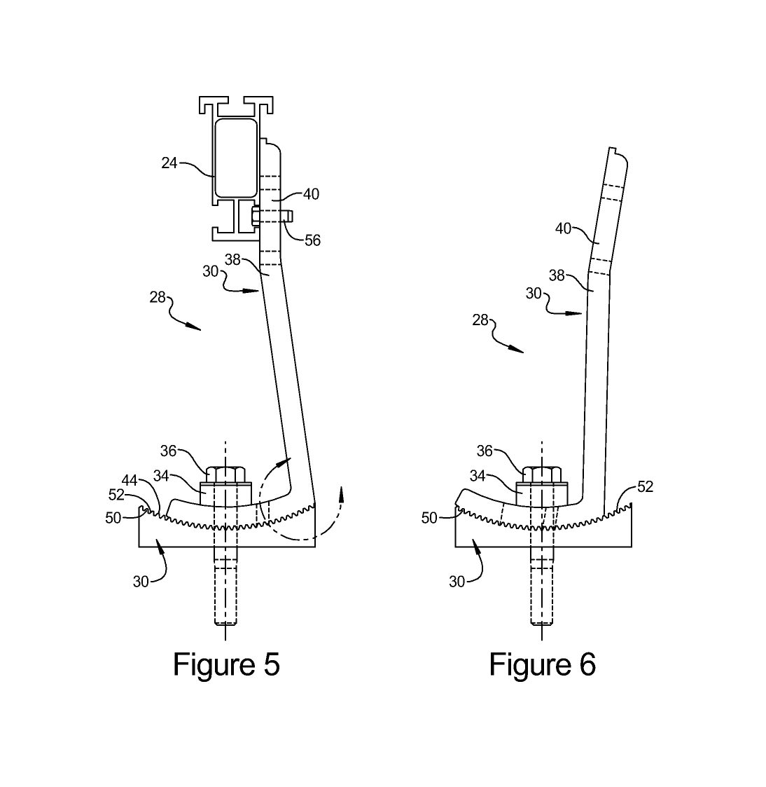

Referring to FIGS. 4 and 5, the slot 42 in the head portion 40 of the L-shaped member 30 allows an external bolt 56 or other suitable fastener to extend there through. This enables the external bolt 56 to secure the frame 24 (FIG. 5) thereto, and where the frame component 24 can in turn be used to support the PV panels 18, 20 and 22 along its length.

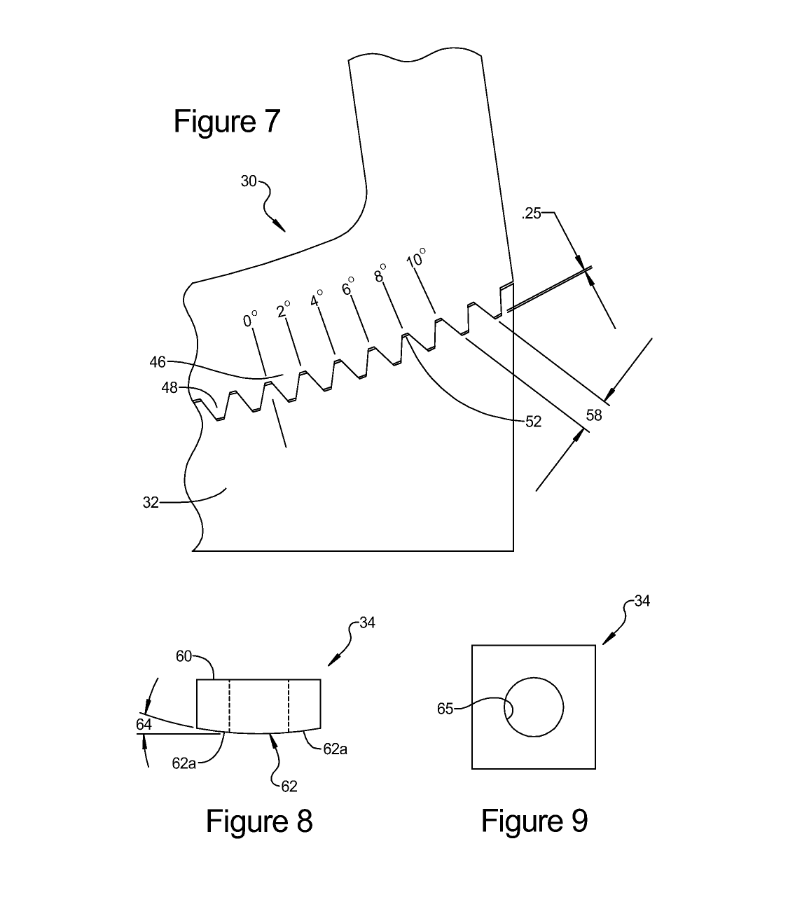

Referring now to FIG. 7, the meshing engagement of the teeth 48 of the L-shaped member 30 and the teeth 52 of the base member 32 can be seen in greater detail. The teeth 48 and 52 are preferably formed and spaced to provide predetermined adjustment increments, in this example about 2.0 degrees per tooth, as indicated by arrows 58. This facilitates positive engagement of the L-shaped component 30 relative to the base member 32 and assists the installer in precisely positioning the L-shaped member 30, relative to the base member 32, to provide the desired degree of inclination.

Referring now to FIG. 8, the washer 34 can be seen to have an upper surface 60 that is flat, and a radiused bottom surface 62. The radiused lower surface 62 has the same, or about the same, radius of curvature as an upper surface 66 of the foot portion 44. In FIG. 9 the washer 34 can be seen to include a hole 65 having a diameter sufficient to allow the threaded portion of the threaded bolt 36 to pass therethrough.

In use the base member 32 and the L-shaped member 30 may be positioned on one of the elongated frame members 26. The L-shaped members 30 may each be positioned to provide the desired inclination before the threaded bolt 36 is tightened down. In this regard each of the base member 32 and the L-shaped member 30 may be provided with suitable markings on side portions thereof, such as on the sides of these components visible in FIG. 4. The marks may correspond to “0”, “2”, “4”, “6”, “8” and “10”, or any other numbering convention to denote how many degrees of inclination will be provided when a mark on the L-shaped member 30 is aligned with a mark on the base member 32. One example of a marking arrangement is shown in FIG. 7. In this way all of the bracket assemblies 28,28′ can be fixedly secured at the desired inclination before proceeding to the next assembly step.

Referring briefly to FIG. 2B, one of the bracket assemblies 28′ can be seen in enlarged fashion. Portions of the bracket assembly 28′ in common with bracket assembly 28 have been denoted using reference numbers in common with those used to describe the bracket assembly 28, but which also include a prime symbol (“′”) after each number. As mentioned above, it will be appreciated that frame member 25 will be spaced a greater distance from the frame members 26 than the frame member 24 will be. This necessitates that the bracket assemblies 28′ used to support the frame member 25 be physically taller than the bracket assemblies 28. This can be accomplished by simply making a neck portion 38′ of the bracket assembly 28′ suitably long to accommodate the maximum anticipated angle of inclination that the bracket assembly 28′ will need to provide. Obviously, the greater the maximum degree of inclination that one desires to achieve, the longer the neck portion 38′ will need to be made. Alternatively, the bracket assembly 28 could be used and an extension component could be fastened to interface the head portion 40 of the L-shaped member 30 to the frame member 25. Such an arrangement is shown in FIG. 2C, where a tubular metallic member 100 has been fastened, using conventional threaded nuts and bolt assemblies 56, to the head portion 40 and also to the frame member 25. Instead of the tubular member 100, a suitably thick piece of metallic material in the form of a plate may be used as well. Still further, as shown in phantom in FIG. 2B, a metallic component 200 could be placed under the base member 32′ or the base member 32 to provide additional elevation. With using the metallic component 200, the length of the shaft of the threaded bolt 36′ will need to be sufficiently lengthened so as to be able to connect the base member 32′ to the frame member 26.

The bracket assemblies 28, 28′ can thus be quickly and easily configured to the desired inclination. Because of the significant degree of inclination adjustability that the bracket assemblies 28,28′ provide, the bracket assemblies 28,28′ can be used in a wide variety of applications where different degrees of inclination are needed. For a manufacturer, this significantly simplifies the manufacture of a PV frame system, as well as reducing the inventory of individual component parts that need to be kept on hand to meet the needs of different installations. Also, if the installer begins an installation and realizes that the needed degree of inclination for a PV panel system is slightly greater or lesser than originally planned for, this is no problem with the bracket assemblies 28,28′. Minor variations in the needed degree of inclination can easily be accommodated.

The foregoing description of the embodiments has been provided for purposes of illustration and description. It is not intended to be exhaustive or to limit the disclosure. Individual elements or features of a particular embodiment are generally not limited to that particular embodiment, but, where applicable, are interchangeable and can be used in a selected embodiment, even if not specifically shown or described. The same may also be varied in many ways. Such variations are not to be regarded as a departure from the disclosure, and all such modifications are intended to be included within the scope of the disclosure.

What is claimed is:

1. A bracket system for use with a photovoltaic panel frame system for assisting in mounting at least one photovoltaic panel at an angle non-parallel to a support surface on which the photovoltaic panel frame system is mounted, the bracket system comprising:
a bracket assembly including:
a first member having a neck portion and a foot portion extending non-parallel to the neck portion, the foot portion having a radius of curvature;
a second member having a first surface having a radius of curvature that generally matches the radius of curvature of the foot portion; and
one of the first member and the second member having an elongated slot formed therein and the other one of the first member and the second member having a hole; and
a fastener adapted to extend through the elongated slot and the hole to secure the first and second members fixedly to a frame system component, and further such that the first member can be secured at a desired inclination relative to the frame system component.

2. The system of claim 1, wherein:
the first member includes a lower surface having a first plurality of teeth, and;
the second member includes an upper surface having a second plurality of teeth; and
wherein the first and second pluralities of teeth engage to assist in maintaining the first member at a desired angular orientation relative to the second member.
